(19) United States
(12) Patent Application Publication
(10) Pub. No.: US 2005/0225376 A1
(43) Pub. Date: Oct. 13, 2005

(54) Adaptive supply voltage body bias apparatus and method thereof

(75) Inventor: Oscar Ming Kin Law, Markham (CA)

Correspondence Address: ATI TECHNOLOGIES, INC.;C/O VEDDER PRICE KAUFMAN & KAMMHOLZ, P.C., 222 N.LASALLE STREET, CHICAGO, IL, 60601, US

(73) Assignee: ATI Technologies, Inc., Markham (CA)

(21) Appl. No.: 10/820,556

(22) Filed: Apr. 8, 2004

(51) Int. Cl. H03K 3/01

(52) U.S. Cl. 327/534

(57) ABSTRACT

An adaptive supply voltage and body bias apparatus includes a master controller including an operation state value. The apparatus and method includes a dynamic voltage supplier coupled to the master controller operative to receive a supply voltage indicator. The apparatus and method includes an adaptive body biaser coupled to the master controller operative to receive a body bias indicator. Furthermore, the apparatus and method includes a plurality of computing devices each having one of a plurality of threshold voltages. The plurality of computing devices are operative to receive the supply voltage from the dynamic voltage supplier and a bias voltage from the adaptive body biaser for optimized power supply in conjunction with reduction of power leakage in view of the varying threshold voltage of the computing devices.

### FIELD OF THE INVENTION

The present invention relates generally to power supply for an integrated circuit and more specifically, to optimizing integrated circuit power consumption through adjustable supply voltage and biasing.

### BACKGROUND OF THE INVENTION

In a typical processing unit, such as an integrated circuit, voltage supply is an important component for efficient operations. Inherent within the integrated circuit is potential for current leakage, wherein a supply voltage is dissipated or ineffectively utilized by the integrated circuit. With increased current leakage, there is a direct reduction in performance of the integrated circuit as well as a direct increase in power requirements.

The integrated circuit is typically composed of multiple computing devices, such as one or more compilations of components for computing a specific function. For example, a device may consist of a series of gates and connections for allowing a specific calculation, such as found within an application specific integrated circuit (ASIC). In a typical processing system, the integrated circuit may include multiple devices, such that the functionality of the integrated circuit is the product of operations of any number of the devices within the integrated circuit. It is also recognized that processing may be performed across multiple integrated circuits co-operation between different devices from different circuits for producing a computed output.

One current approach for multiple devices having different threshold voltages is applying a variable supply voltage (VDD) and another approach is to provide a constant supply voltage. With the increase of nanometer technology, and the higher frequency of devices within an integrated circuit, more leakage is generated. As such, total power is increased dramatically without a direct increase in system performance. Thereupon, this generates multiple problems including effecting the speed or performance of an integrated circuit, increasing power consumption and leakage and requiring a greater amount of active power for a system.

A first approach to overcome these limitations is commonly known as a Dynamic Voltage Scale (DVS) approach. The DVS approach for power consumption is directed primarily to active power reduction. The DVS approach ignores current leakage. The DVS approach is a well-known approach recognized by one having ordinary skill in the art, wherein active power is reduced without effectuating body bias or controlling threshold voltages for various devices within the integrated circuit. As noted, the DVS approach ignores current leakage and therefore can produce a system having high power requirements with low leakage saving efficiency.

In the current approach, multi-threshold devices topology is used, low threshold voltage devices with higher current leakage are used to receive performance requirements in critical paths and high threshold voltage devices with lower leakage are used for other logic. Therefore, critical path components generate a higher current leakage, but the system compensates through having lower leakage rate with noncritical logic. Overall power consumption may be controlled using this approach, but does not provide for an efficient correlation between critical path devices, non-critical path devices and threshold voltages.

A second approach to overcome power consumption requirements is an Adaptive Body Bias (ABB) approach. The ABB approach controls the threshold voltage only for the purpose of generating leakage reduction. The ABB approach adjusts a body bias voltage by a particular amount to thereby allow for a constant supply voltage relative to device threshold voltages. Similar to the DVS approach, the ABB approach provides a compromise between power requirements for critical path devices and current leakage based on threshold voltages. While the DVS approach ignores leakage in view of active power reduction, the ABB approach reduces leakage by controlling the threshold voltage. The ABB approach is limited because, among other things, it fails to optimize threshold voltage for all devices at the cost of seeking current leakage reduction for the overall system.

A more recent approach for overcoming limitations with active power reduction and voltage leakage reduction is a total power reduction approach that combines the DVS approach and the ABB approach for both actual power and leakage control, Adaptive Supply Voltage and Body Bias (ASB). The ASB approach was developed by Hitachi in combination with the Massachusetts Institute of Technology (MIT). This power reduction and leakage reduction approach is well known by one having ordinary skill in the art. Although, the ASB approach is limited to one or more devices having a common threshold voltage. Therefore, the ASB approach is significantly limited to applications in which all devices have the same threshold voltages.

In the current nanometer generation, the silicon has reached its physical limitations and computing device voltage leakage is exponentially increasing. The leakage of both low threshold voltage devices and the high threshold voltage devices is almost an order of magnitude higher than current leakage rates. Therefore, the DVS approach and ABB approach are no longer used for future generations due to the cumulative effect of leakage and efficiency based on threshold voltage, respectively. Furthermore, in the increase of devices on an integrated circuit, the ASB approach is limited based on the devices having multiple threshold voltages.

As such, there exist a need for controlling active power consumption and reducing voltage leakage in an integrated circuit having devices with different threshold voltages.

### BRIEF DESCRIPTION OF THE DRAWINGS

FIG. 1 illustrates a schematic block diagram of an adaptive supply voltage and body bias apparatus in accordance with one embodiment of the present invention;

FIG. 2 illustrates a graphical representation of multiple threshold voltage devices;

FIG. 3 illustrates another embodiment of an adaptive supply voltage and body bias apparatus;

FIG. 4 illustrates a chart representing operation state values and corresponding supply voltage embodied by its values, in accordance with one embodiment of the present invention;

FIG. 5 illustrates a graphical representation of one embodiment of a frequency monitor of FIG. 3;

FIG. 6 illustrates a plurality of gates representing different computing devices;

FIG. 7 illustrates a flow chart of a method for adaptive supply voltage and body bias in accordance with one embodiment of the present invention; and

FIG. 8 illustrates a flowchart of another method for adaptive supply voltage and body bias in accordance with another embodiment of the present invention.

### DETAILED DESCRIPTION OF A PREFERRED EMBODIMENT OF THE INVENTION

Generally, an adaptive supply voltage and body bias apparatus and method thereof includes a master controller including an operation state value. The master controller may be any suitable processing device disposed within hardware, software or combination thereof performing the below-noted functionality. An operation state value may be any type of indicator indicating a type of operations state, such as and not limited to a supercharge state, a high performance state, a moderate performance state, a low performance state, and a standby mode, wherein the states indicate the operations level of an integrated circuit.

The apparatus and method further includes a dynamic voltage supplier operably coupled to the master controller, the dynamic voltage supplier operative to receive a supply voltage indicator. The dynamic voltage supplier may be any suitable standard dynamic voltage supplier as recognized by one having ordinary skill in the art. The supply voltage indicator may be any suitable indicator indicating a corresponding supply voltage, such as but not limited to a particular voltage level. The apparatus and method thereof further includes an adaptive body biaser operably coupled to the master controller, the adaptive body biaser operative to receive a body bias indicator. The adaptive body biaser may be any suitable adaptive body biaser as recognized by one having ordinary skill in the art. The body bias indicator may be any suitable indicator capable of providing an indication of a corresponding body bias value.

The apparatus and method thereof further includes a plurality of computing devices, wherein each of the computing devices has one of multiple different threshold voltages. The plurality of computing devices is operative to receive a supply voltage from the dynamic voltage supplier and a bias voltage from the adaptive body biaser. Therein, the multiple threshold voltage devices may perform their corresponding operations using the incoming body bias values and threshold voltages with a concurrent reduction in voltage leakage while maintaining effective utilization of an active power source, in response to an operation state determined by the operations state value within the master controller.

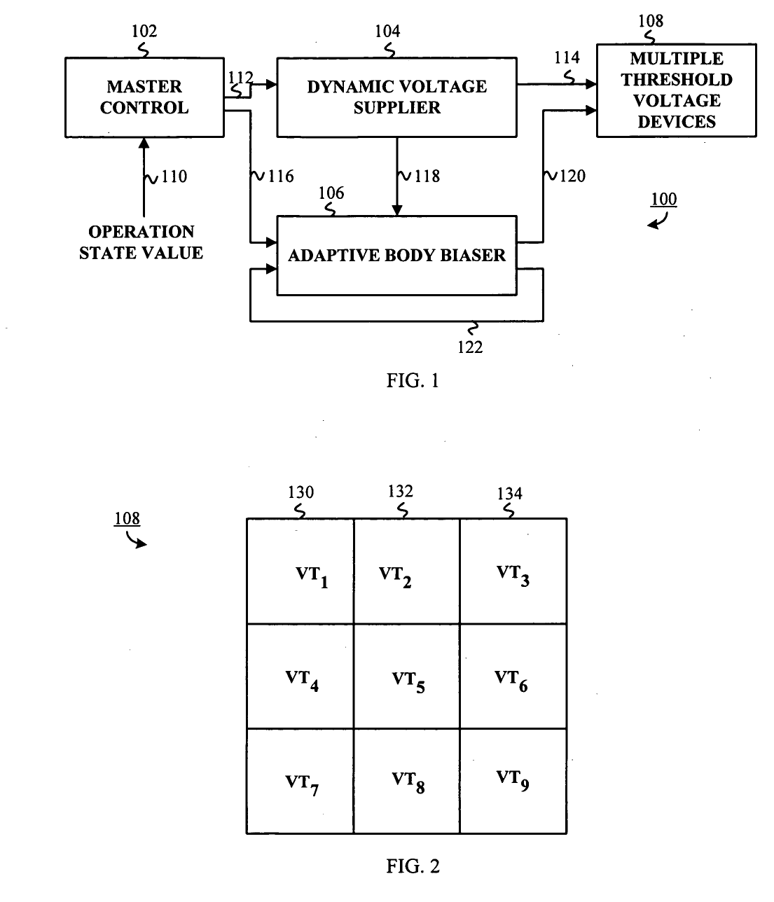

More specifically, FIG. 1 illustrates an adaptive supply voltage and body bias apparatus using a multi-threshold, supply and bias architecture (MTSB) 100. The MTSB architecture 100 includes a master controller 102, a dynamic voltage supplier 104, an adaptive body bias 106 and multiple threshold voltage devices 108. The master controller 102 receives an operations state value 110. The operation state value 110 may be received from any suitable outside source, such as a control processor. In another embodiment, the master controller 102 may include a look-up table having operations state values stored therein and the master controller 102 operative to receive an indicator such that a operations state value 110 may be retrieved from the internal look-up table within the master controller 102.

Regardless therefore, the master controller 102 in response to the operations state value 110 generates a supply voltage indicator 112. The dynamics voltage supplier 104 receives the supply voltage indicator 112 from the master controller 102. In one embodiment, the supply voltage indicator may be an actual voltage value or in another embodiment may be any suitable indicator indicating the corresponding requested voltage output from the dynamic voltage supplier 104. In response to the supply voltage indicator 112, the dynamic voltage supplier 104 generates a supply voltage 114. The multiple threshold voltage devices 108 receive the supply voltage 114 as a power source for powering the multiple devices, wherein the devices have different threshold voltages.

The master controller 102, furthering responding to the operations state value 110, generates a body bias indicator 116. The adaptive body biaser 106 receives the body bias indicator 116 and generates a bias voltage 120 therefrom. The body bias indicator 116 may be a voltage value or may be any suitable indicator indicating a corresponding bias voltage 120 generated by the adaptive body biaser 106. As noted above, the adaptive body biaser 106, operates in accordance with known operating techniques as recognized by one having ordinary skill in the art. The bias voltage 120 may be a backward bias voltage or a forward bias voltage. The multiple threshold voltage devices 108 receives the bias voltage from the adaptive body biaser 106 for powering up and performing the designated functions for each of the devices within the multiple threshold devices 108.

The adaptive body biaser 106 also receives voltage indicator 118 from the dynamic voltage supplier 104. The voltage indicator 118 indicates the voltage level of the supply voltage 114 provided to the multiple threshold voltage devices 108. The adaptive body biaser 106 further includes a feedback loop 122, which provides feedback and iterative knowledge for the adaptive body biaser 106 in determining the bias voltage 120 including tracking the local body bias variation. Therefore, in accordance with known adaptive body biaser 106 operations, the bias voltage 120 is generated based on not only the body bias indicator 116, voltage indicator 118, but also the feedback 122. In another embodiment, a feedback signal may be included within the dynamic voltage supplier 104 to compensate the local supply voltage variation.

FIG. 2 states a graphical representation of the multiple threshold voltage devices 108 including multiple threshold devices, such as devices 130, 132 and 134. In a typical embodiment, the different devices 130, 132 and 134 have different threshold voltages based on different operations. In the MTSB architecture 100, low threshold voltage devices are defined within the critical path and high threshold devices are in other logic with backward biasing at lower supply voltages to reduce overall power. Since the high threshold voltage device is used, it eliminates additional leakage dissipated in non-critical paths. However, different threshold voltage devices usage is highly dependent on system requirement which is not limited to above implementation. Moreover, as the power is highly dependent on the supply voltage, the lower supply voltage thereby increases power savings. As recognized by one having ordinary skill in the art, the multiple threshold voltage devices 108 may be any suitable shape encompassing any suitable number of processing elements, but the device 108 is illustrated in a matrix for exemplary purposes only and is not meant to be so limiting herein. Moreover, further discussion regarding the individual specific devices, such as 130, 132 or 134 are discussed in further detail below with regards to FIG. 6.

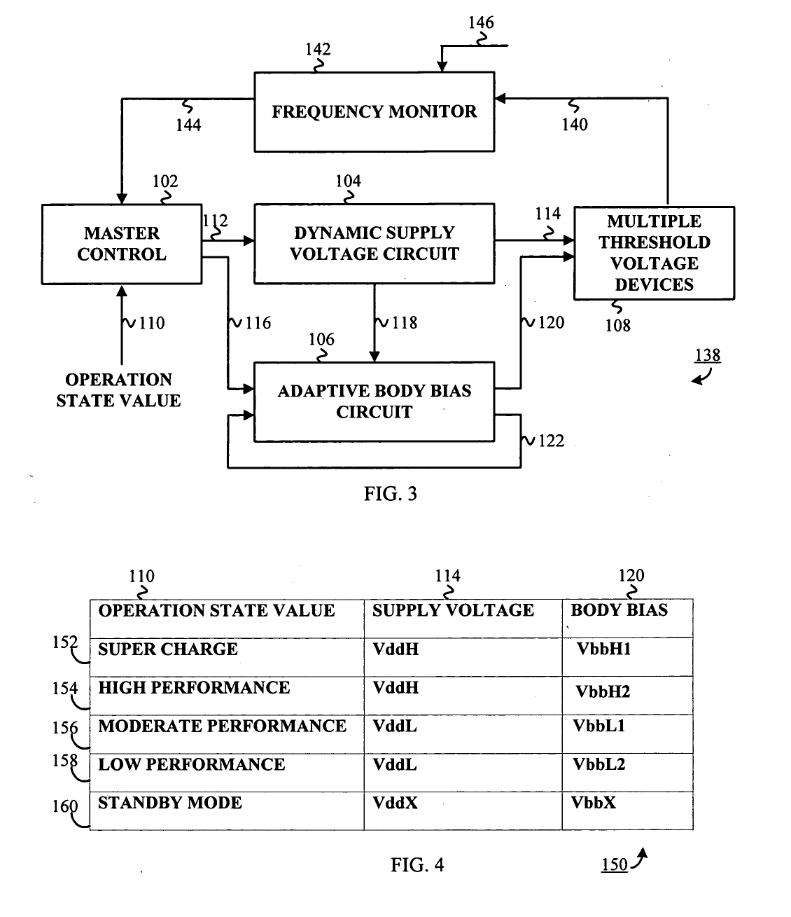

FIG. 3 illustrates another embodiment of an adaptive supply voltage and body bias apparatus 138 using the MTSB architecture. The apparatus 138, similar to the apparatus 100 of FIG. 1, includes the master controller 102, the dynamic voltage supply circuit 104, the adaptive body bias circuit 106 and the multiple threshold voltage devices 108. The master controller 102 receives the operation state value 110 and generates the supply voltage indicator 112 and the body bias indicator 116. The dynamic supply voltage circuit 104 generates the supply voltage 114 and the adaptive body bias circuit 106 generates the bias voltage 120 in response to the voltage indicator 118, the body bias indicator 116 and the feedback 122.

In one embodiment, the multiple threshold voltage devices 108 generate an output frequency indicator 140. The frequency measure is based on the phase difference between the sample circuit output and reference signal. The output frequency indicator 140 may be any suitable indicator, indicating an output frequency value generated by the multiple threshold voltage devices 108, including in one embodiment an actual frequency value or another embodiment indicators representing the particular frequency values or frequency ranges. A frequency monitor 142 receives the output frequency indicator from the multiple threshold voltage devices 108, wherein the multiple threshold voltage devices 108 are also referred to as multiple computing devices having varying threshold voltages.

The frequency monitor 142 generates a frequency offset value 144, wherein the frequency offset value 144 is based on a comparison of the output frequency indicator 140 and a reference frequency indicator 146. The reference frequency indicator 146 may be any suitable indicator indicating a standard frequency value for optimized performance by the multiple threshold voltage devices 108. Therefore, the frequency offset value 144 indicates a difference between actual frequency performance of the computing devices within the multiple threshold voltage devices 108 and the reference frequency indicator 146.

The master controller 102 receives the reference frequency indicator 144. The master controller 102 thereupon generates a second supply voltage indicator in a second body bias indicator, similar to 112 and 116 respective, in response to the frequency offset value 144 and the operations state value 110. The dynamic supply voltage circuit 104 receives the second supply voltage indicator, similar to indicator 112, and the adaptive body bias circuit 106 receives the second body bias indicator, similar to the body bias indicator 116. The dynamic supply voltage circuit 104 generates a second supply voltage, similar to supply voltage 114, in accordance with standard dynamic supply voltage circuit operations. The adaptive body bias circuit 106 generates a second bias voltage, similar to bias voltage 120, in accordance with standard adaptive body bias circuit operations.

Thereupon, the multiple threshold voltage devices 108 receive the second supply voltage from the dynamic supply voltage circuit 104 and the second bias voltage from the adaptive body bias circuit 106. In response thereto, the computing devices having the multiple threshold voltages 108 are further tuned for efficient operation including the proper power reduction based on the supply voltage, such as supply voltage 114 or the second supply voltage, in combination with corresponding body biasing, such as the bias voltage 120 and the second bias voltage.

FIG. 4 illustrates a table 150 illustrating different operation state values 110, corresponding supply voltage 114 and body bias voltage 120. The table 150 illustrates exemplary embodiments of various operational operation state values 110, but as recognized by one having ordinary skill in the art, any other suitable operation state values 110 may be designated and corresponding supply voltages 114 and body bias voltage 120 may be associated therewith.

The first operation state 110 value is a supercharged state 152 that includes a high supply voltage 114 VddH and a body bias 120 of zero. When the operation state value 110 indicates high performance 154, the supply voltage 114 is once again a high supply voltage, VddH and a body bias voltage 120 is high, VbbH. If the operation state value 110 indicates moderate performance, 156, the supply voltage 114 is low, VddL and the body bias voltage 120 is zero. The operation state value 110 indicates low performance 158, the supply voltage 114 is set low and the body bias voltage 120 is also set low. While in a standby mode 160, the supply voltage 114 and the body bias voltage 120 are both set to a standby voltage, which may be a very low voltage level relative to even the low voltage levels of the VddL and VbbL.

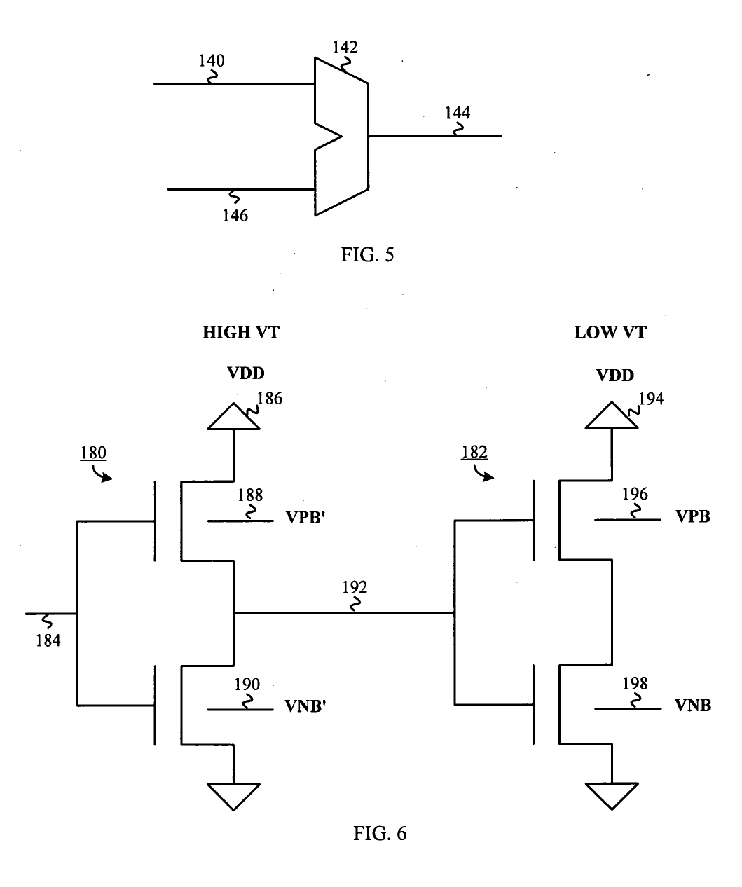

FIG. 5 illustrates a graphical representation of the frequency monitor 142 receiving the output frequency 140, the reference frequency 146 and therein generating the offset frequency 144. In one embodiment, the frequency monitor 142 may be a simple comparator, which allows for generating a delta value between the output frequency 140 and the reference frequency 146. As recognized by one have ordinary skill in the art, any other suitable method may be utilized to determine a frequency difference between the output frequency 140 from the multiple threshold voltage devices 108 and the reference frequency 146 to generate the offset frequency 144.

FIG. 6 illustrates two computing devices 180 and 182 having different threshold voltages. The device 180 has a high threshold voltage and the device 182 has a low threshold voltage. As recognized by one having ordinary skill in the art, the biasing voltage is composed of a p-substrate bias voltage for p-type devices and n-substrate bias voltage for n-type devices, illustrated as device 180. The device 180 receives input voltage 184 The bias voltage is then determined across the gates, wherein the bias voltages in the high threshold voltage device 180 include the p-substrate bias voltage (Vpb′) 188 and the n-substrate bias voltage (Vnb′) 190.

Similar to the first computing device 180, the second computing device 182 has the threshold voltage Vdd 194 which is provided across the p-junction and the n-junction to generate the p-substrate bias voltage (Vpb) 196 and the n-substrate bias voltage (Vnb) 198. These voltages are in response to the input voltage 192, wherein the computing device 182 has a low threshold voltage. The substrate bias voltages can be same or different dependent on the applications, it means that the same p-substrate bias voltages (Vpb′) and (Vpb) can be applied for both high/low threshold voltage p-type devices or they can be adjusted differently for various threshold voltage devices, the same principle is apply for n-substrate bias voltages (Vnb′) and (Vnb) for n-type devices.

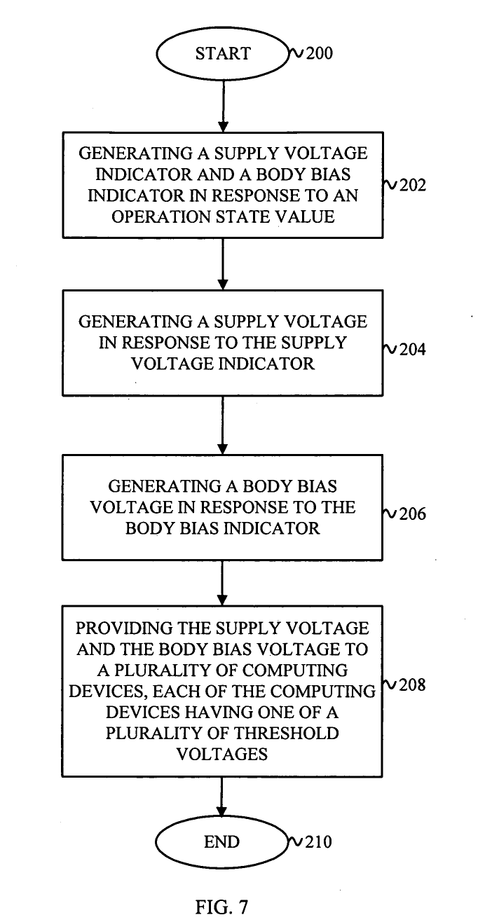

FIG. 7 illustrates one embodiment of a method for adaptive supply voltage and body bias, 200. The method begins, step 202, by generating a supply voltage indicator and a body bias indicator in response to an operation state value. As discussed above with regards to FIG. 1, a supply voltage indicator 112 and a body bias indicator 116 are generated in response to the operation state value 110. The next step, step 204, is generating a supply voltage in response to the supply voltage indicator. In one embodiment, the dynamic voltage supplier 104 performs this operation. The next step, step 206, is generating a body bias voltage in response to the body bias indicator. In one embodiment, the adaptive body bias 106 thereupon performs this operation to generate the body bias voltage 120. It should also be noted in another embodiment that the body bias indicator 120 is generated in response to a voltage indicator 118 and feedback 122, as illustrated in FIG. 1.

Step 208 is supply the supply voltage and the body bias voltage to a plurality of computing devices, each of the computing devices having one of a plurality of threshold voltages. Referring back to FIG. 1, the supply voltage 114 and the body bias voltage 120 are provided to the multiple threshold voltage devices 108, wherein the devices 108 have different threshold voltages. As such, the method allows for adaptive supply voltage and body bias through providing a generated bias voltage and supply voltage for multiple computing devices having varying threshold voltages. As such, in one embodiment of the present invention, the method is complete, step 210.

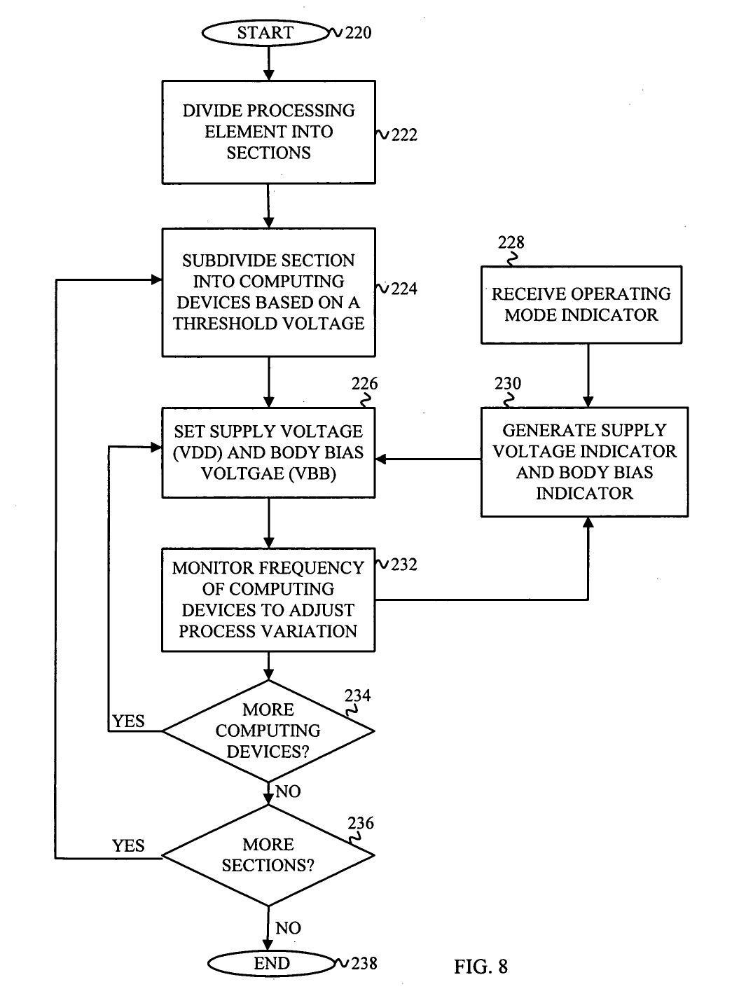

FIG. 8 illustrates a method for tuning a supply voltage and body biasing for a processing device having computing devices with different threshold voltages. The method begins with step 200, by dividing the processing element into particular sections, step 222. For exemplary purposes only, referring back to FIG. 2, the processing element may be element 108 and sections defined as specific devices such as 130, 132 and 134. As recognized by one having ordinary skill in the art, further division may be conducted such as dividing the device 130 into further subdevices based on processing elements and density of prefacing components within the computing device.

The next step is subdividing sections into computing devices based on a threshold voltage, step 224. As described above, individual sections may be further subdivided, wherein the subdivisions have different threshold voltages. The next step, step 226, is to set a supply voltage (Vdd) and a body bias voltage (Vbb) for the computing device. Prior to step 226, the method includes receiving an operating mode indicator 228, such as an operation state value 110 illustrated in FIGS. 1 and 3 and generating a supply voltage indicator and body bias indicator, step 230.

As discussed above, the master controller 102 may be utilized to generate the supply voltage indicator 112 and the body bias indicator 116. With the supply voltage indicator and the body bias indicator, step 226 allows for setting the supply voltage and bias body voltage. The next step is to monitor the frequency of computing devices to adjust process variations, step 232. The process variation is due to the chemical doping non-uniformly distributed across the die. Therein, if the frequency indicates that further adjustments should be made for a particular computing device, the method proceeds to step 230 where another supply voltage indicator and body bias indicator are generated such that step 226 may be repeated to set another supply voltage and another body bias voltage.

In one embodiment, steps 232, 230 and 226 are similar to the operations described above with regards to FIG. 3. Once it is determined that the process variations are within a defined parameter, the next step, step 234, is determining if there are more computing devices. If there are more computing devices, the method proceeds back to step 226 wherein steps 226, 230 and 232 are repeated for each computing device. When a determination is made that there are no more computing devices, the next step, step 236, is to determine if there are more sections of the processing element. If there are more sections of the processing element, the method reverts back to step 224 for operation of steps therein.

The method is continued for each computing device in the section and then the method is once again repeated for each section. When it is determined that there are no more sections, in one embodiment of the present invention, the method is complete, step 238.

As such, the present invention allows for the achievement of equivalent performance with high density processing elements having multiple processing devices with varying threshold voltages. Higher threshold voltage devices have a voltage range, in one embodiment, from 1.0 volts to 1.2 volts and lower threshold voltage devices may be biased with a 1 volt voltage supply, in one embodiment, thereby reducing the maximum power consumption by 20 to 40%. High voltage leakage is avoided using a forward bias wherein in one embodiment the body bias may be defined between −1.0 volt and 0.5 volts.

If the device is forward biased above certain level, leakage may be significantly increased and the magnitude of leakage is even higher than benefits using active power. Through the utilization of feedback, such as illustrated in FIG. 3, the MTSB architecture employs, in one embodiment, low threshold voltage devices in critical paths and high threshold voltage devices in other logic. Additional voltage leakage is dissipated in non-critical paths and the MTSB approach can be easily integrated with multi-threshold voltage designs.

The body bias may be dynamically adjusted to overcome the process parameter variations, therefore overall speed performance of a processing device may be consistent. The present invention improves over the prior art by not only incorporating both the dynamic voltage supplier 104 and the adaptive body bias 106 in conjunction with a master controller 102, but is also applicable to computing devices having multiple threshold voltages, such as the multiple threshold voltage devices 108. Prior techniques were limited to only dynamic voltage supply, only adaptive body bias or combining the dynamic voltage supply and adaptive body bias to processing elements having the same threshold voltage. Wherein, the present invention allows for applicability to computing devices having varying threshold voltages.

It should be understood that the implementation of other variations and modifications of the invention and its various aspects will be apparent to those of ordinary skill in the art, and that the invention is not limited by the specific embodiments described herein. For example, the frequency monitor 142 may be incorporated within the master controller 102 and utilize a straight comparator or any other suitable means for converting a frequency value to generate the frequency offset value 144 so the master controller 102 may thereupon provide updated voltage and body bias commands to the dynamic supply voltage circuit 104 and adaptive body bias circuit 106. It is therefore contemplated to cover by the present invention, any and all modifications, variations, or equivalents that follow in the spirit and scope of the basic underlying principles disclosed and claimed herein.

1. An adaptive supply voltage and body bias apparatus comprising:
a master controller including an operation state value;
a dynamic voltage supplier operably coupled to the master controller, the dynamic voltage supplier operative to receive a supply voltage indicator;
an adaptive body biaser operably coupled to the master controller, the adaptive body biaser operative to receive a body bias indicator; and
a plurality of computing devices, each of the computing devices having one of a plurality of threshold voltages, the plurality of computing devices operative to receive a supply voltage from the dynamic voltage supplier and a bias voltage from the adaptive body biaser.

2. The adaptive supply voltage and body bias apparatus of claim 1 further comprising:
a frequency monitor operably coupleable to the plurality of computing devices, the frequency monitor operative to receive an output frequency indicator from at least one of the plurality of computing devices.

3. The adaptive supply voltage and body bias apparatus of claim 2 wherein the frequency monitor generates a frequency offset value.

4. The adaptive supply voltage and body bias apparatus of claim 3 wherein the frequency offset value is based on a comparison of the output frequency indicator and a reference frequency indicator.

5. The adaptive supply voltage and body bias apparatus of claim 3 wherein the frequency offset value is provided to the master controller, the master controller generating a second supply voltage indicator and a second body bias indicator in response to the frequency offset value and the operation state value, the master controller operative to provide the second supply voltage indicator to the dynamic voltage supplier and operative to provide the second body bias indicator to the adaptive body bias circuit.

6. The adaptive supply voltage and body bias apparatus of claim 5 further comprising:
the plurality of computing devices operative to receive a second supply voltage from the dynamic voltage supplier and a second bias voltage from the adaptive body biaser.

7. The adaptive supply voltage and body bias apparatus of claim 1 wherein the master controller receives the operation state value from a processing device.

8. The adaptive supply voltage and body bias apparatus of claim 1 wherein the plurality of computing devices are disposed on a processing element.

9. The adaptive supply voltage and body bias apparatus of claim 1 wherein the supply voltage indicator and the body bias indicator are voltages.

10. A method for adaptive supply voltage and body bias, the method comprising:
generating a supply voltage indicator and a body bias indicator in response to an operation state value;
generating a supply voltage in response to the supply voltage indicator;
generating a body bias voltage in response to the body bias indicator; and
providing the supply voltage and the body bias voltage to a plurality of computing devices, each of the computing devices having one of a plurality of threshold voltages.

11. The method of claim 10 further comprising:
generating an output frequency from at least one of the plurality of computing devices;
providing the output frequency to a frequency monitor; and
generating a frequency offset value based on the output frequency and a reference frequency.

12. The method of claim 11 further comprising:
providing the frequency offset value to a master controller;
generating a second supply voltage indicator and a second body bias indicator in response to the frequency offset value and the operation state value; and
providing the second supply voltage indicator to a dynamic voltage supplier and the second body bias indicator to an adaptive body biaser.

13. The method of claim 12 further comprising:
generating a second supply voltage;
generating a second body bias voltage; and
providing the second supply voltage and the second body bias voltage to the plurality of computing devices.

14. The method of claim 10 further comprising:
receiving the operation state value from a processing device.

15. The method of claim 10 wherein the plurality of computing devices are disposed on a processing element.

16. An adaptive supply voltage and body bias apparatus comprising:
a master controller operative to receive an operation state value, the master controller operative to generate a supply voltage indicator and a body bias indicator based on the operation state value;
a dynamic voltage supplier operably coupled to the master controller, the dynamic voltage supplier operative to receive the supply voltage indicator;
an adaptive body biaser operably coupled to the master controller, the adaptive body biaser operative to receive the body bias indicator;
a plurality of computing devices, each of the computing devices having one of a plurality of threshold voltages, the plurality of computing devices operative to receive a supply voltage from the dynamic voltage supplier and a bias voltage from the adaptive body biaser;
a frequency monitor operably coupleable to the plurality of computing devices, the frequency monitor operative to receive an output frequency indicator at least one of the plurality of computing devices.

17. The adaptive supply voltage and body bias apparatus of claim 16 wherein the frequency monitor generates a frequency offset value based on a comparison of the output frequency indicator and a reference frequency indicator.

18. The adaptive supply voltage and body bias apparatus of claim 17 wherein the frequency offset value is provided to the master controller, the master controller generating a second supply voltage indicator and a second body bias indicator in response to the frequency offset value and the operation state value, the master controller operative to provide the second supply voltage indicator to the dynamic voltage supplier and operative to provide the second body bias indicator to the adaptive body bias circuit.

19. The adaptive supply voltage and body bias apparatus of claim 18 further comprising:
the plurality of computing devices operative to receive a second supply voltage from the dynamic voltage supplier and a second bias voltage from the adaptive body biaser.

20. A method for tuning a supply voltage and a body bias for a processing device, the method comprising:
for a first sub-section of the processing device:
(a) generating a supply voltage indicator and a body bias indicator in response to an operation state value;
(b) generating a supply voltage in response to the supply voltage indicator;
(c) generating a body bias voltage in response to the body bias indicator;
(d) providing the supply voltage and the body bias voltage to a plurality of computing devices, each of the computing devices having one of a plurality of threshold voltages;
(e) generating an output frequency with at least one of the plurality of computing devices;
(f) generating a frequency offset value based on the output frequency and a reference frequency; and
(e) updating the supply voltage and the body bias voltage in response to the frequency offset value and the operation state value.

21. The method of claim 20 further comprising:
dividing the processing device into a plurality of sub-sections, wherein each sub-section includes the plurality of computing devices, each of the plurality of computing devices have one of a plurality of threshold voltages.

22. The method of claim 21 further comprising:
repeating steps (a) through (e) for each of a plurality of sub-sections of the processing device.

23. The method of claim 22 wherein the operating state value may be one of a plurality of values for each of the sub-sections.
